(19) United States
(12) Patent Application Publication
(10) Pub. No.: US 2026/0189219 A1
(43) Pub. Date: Jul. 2, 2026

(54) RETENTION FLIP-FLOP WITH MULTIPLE DATA RETENTION PATHS

(71) Applicant: GlobalFoundries U.S. Inc., Malta, NY (US)

(72) Inventors: Dzung T. Tran, Austin, TX (US); Uttam Saha, San Jose, CA (US); Navneet K. Jain, Milpitas, CA (US); Arif A. Siddiqi, Milpitas, CA (US); Byung S. Kim, Mountain House, CA (US)

(21) Appl. No.: 19/005,690

(22) Filed: Dec. 30, 2024

(51) Int. Cl. H03K 3/037

(52) U.S. Cl. CPC H03K 3/037

(57) ABSTRACT

A structure includes: a first latch, which is powered on during a normal operating mode and powered off during a data retention mode; a second latch, which is continuously powered on regardless of the mode; and a switch (e.g., a transmission gate) connected between the two latches. The first latch includes a data retention structure (including a combination of feedforward and feedback paths) configured to avoid data loss when a clock signal that controls flip-flop operation is static for some extended period of time. The second latch includes a keeper loop configured to avoid data loss when the first voltage domain is powered off during the data retention mode. The first latch is controlled, in part, by a single-phase clock signal. The second latch is controlled, in part, by either a dual-phase clock signal or combination of a single-phase clock signal and an intermediate signal from the first latch.

### BACKGROUND

The present disclosure relates to flip-flop circuits and, more particularly, to embodiments of a retention flip-flop circuit.

A retention flip-flop is a clock-controlled circuit including multiple latches. Typically, a retention flip-flop includes a total of thirty or more transistors and latches are controlled by a dual-phase clock signal or some other multi-phase clock signal. The retention flip-flop operates in two modes: a normal operating mode and a data retention mode (also referred to as a standby or sleep mode). During the normal operating mode, all latches within the retention flip-flop are powered on. As a data input signal (D) is received at a data input node, it is temporarily stored and a corresponding data out signal (Q) is output from a data output node as a function a dual-phase or multi-phase clock signal. When the retention flip-flop switches from the normal operating mode to the data retention mode, the last data value received by a primary latch is captured by a secondary latch. The primary latch is powered down to conserve power, while the secondary latch remains powered on in order to retain the captured data value. When the retention flip-flop switches from the data retention mode back to the normal operating mode, the primary latch is powered back on and the captured data value will, as a function of the dual-phase or multi-phase clock signal, be transmitted to the data output node. Unfortunately, such conventional retention flip-flops may consume a significant amount of chip area (e.g., due to the relatively large numbers of transistors incorporated therein), may consume a significant amount of power, and may exhibit poor performance, such as a relatively slow operating speed (e.g., due to having a relatively large number of clock nodes).

### SUMMARY

Disclosed herein are embodiments of a circuit structure including a retention flip-flop. Specifically, in each of the disclosed embodiments the structure can include a first latch in a first voltage domain. The first latch can include four logic devices connected between a data input node and a data output node. The four logic devices can include: a first logic device, a second logic device connected to the first logic device at a first intermediate node, a third logic device connected to the second logic device at a second intermediate node, and a fourth logic device connected to the third logic device at a third intermediate node. The first latch can also include a data retention structure. This data retention structure can include pair of transistors connected in series to the second intermediate node and having gates connected to the first intermediate node and the third intermediate node, respectively. The structure can also include a second latch and a switch in a second voltage domain. The switch can have a first terminal connected to the third intermediate node of the first latch and a second terminal connected to a fourth intermediate node of the second latch.

In some embodiments, the structure can include a first latch in a first voltage domain. The first latch can include four logic devices connected between a data input node and a data output node. The four logic devices can include: a first logic device, a second logic device connected to the first logic device at a first intermediate node, a third logic device connected to the second logic device at a second intermediate node, and a fourth logic device connected to the third logic device at a third intermediate node. The first latch can also include a data retention structure including: a pair of N-type field effect transistors (NFETs) connected in series to the second intermediate node and having gates connected to the first intermediate node and the third intermediate node, respectively. The structure can also include a second latch and a switch in a second voltage domain. The switch can have a first terminal connected to the third intermediate node of the first latch and a second terminal connected to a fourth intermediate node of the second latch.

In other embodiments, the structure can include a first latch in a first voltage domain. The first latch can include four logic devices connected between a data input node and a data output node. The four logic devices can include: a first logic device, a second logic device connected to the first logic device at a first intermediate node, a third logic device connected to the second logic device at a second intermediate node, and a fourth logic device connected to the third logic device at a third intermediate node. The first latch can also include a data retention structure including: a pair of P-type field effect transistors (PFETs) connected in series to the second intermediate node and having gates connected to the first intermediate node and the third intermediate node, respectively. The structure can also include a second latch and a switch in a second voltage domain. The switch can have a first terminal connected to the third intermediate node of the first latch and a second terminal connected to a fourth intermediate node of the second latch.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1A and 1B are schematic diagrams illustrating embodiments of a structure including a retention flip-flop;

FIG. 2 is a timing diagram illustrating operation of a retention flip-flop of the structure of FIG. 1A or 1B in both a normal operating mode and a data retention mode when a received data input signal has a logic value of 1;

FIG. 3 is a timing diagram illustrating operation of a retention flip-flop of the structure of FIG. 1A or 1B in both a normal operating mode and a data retention mode when a received data input signal has a logic value of 0; and

FIG. 4 is a schematic diagram illustrating another embodiment of a structure including a retention flip-flop.

### DETAILED DESCRIPTION

As mentioned above, conventional retention flip-flops may consume a significant amount of chip area (e.g., due to the relatively large numbers of transistors incorporated therein), may consume a significant amount of power, and may exhibit poor performance, such as relatively slow operating speeds (e.g., due to having a relatively large number of clock nodes).

In view of the foregoing, disclosed herein are embodiments of a structure including a retention flip-flop. This retention flip flop can include: a first latch, which operates in a first voltage domain, is powered on during a normal operating mode, and is powered off in a data retention mode; a second latch, which operates in a second voltage domain and remains continuously powered on regardless of the mode; and a switch (e.g., a transmission gate) connected between the two latches. The first latch can include a data retention structure (including a combination of feedforward and feedback paths) configured to avoid data loss when a single-phase clock signal that controls flip-flop operation is static for some extended period of time. The second latch can include a keeper loop configured to avoid data loss when the first voltage domain is powered off. In some embodiments, the second latch can be controlled, in part, by a dual-phase clock signal. In other embodiments, the second latch can be controlled, in part, by a combination of the same single-phase clock signal that controls the first latch and an intermediate signal from a node within the first latch. Configured, as described in greater detail below, the disclosed retention flip-flops may consume less chip area (e.g., due to having fewer transistors), may consume less power, and may exhibit better performance, such as faster operating speeds (e.g., due to having fewer clock nodes) than conventional retention flip-flops.

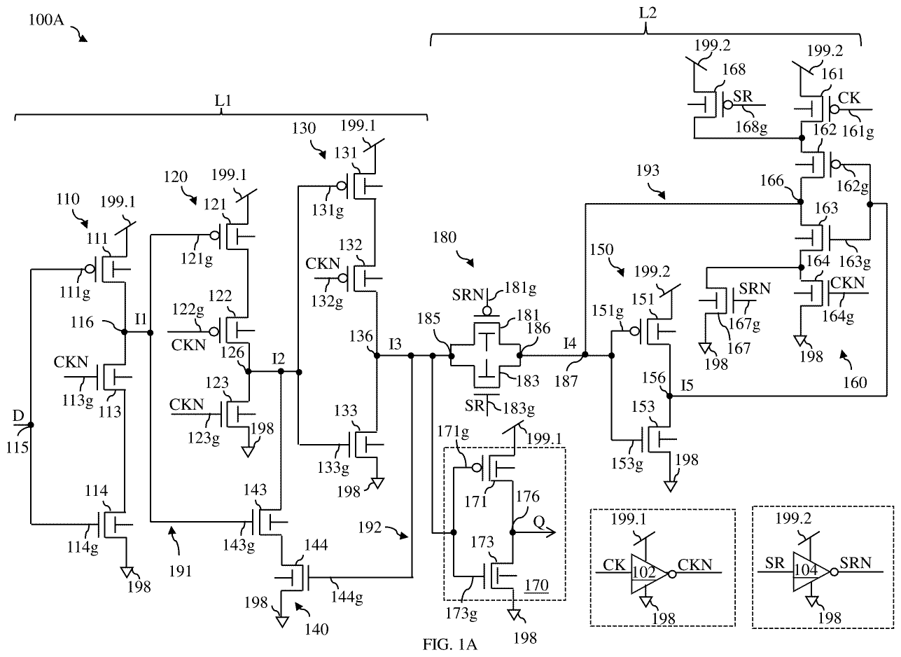

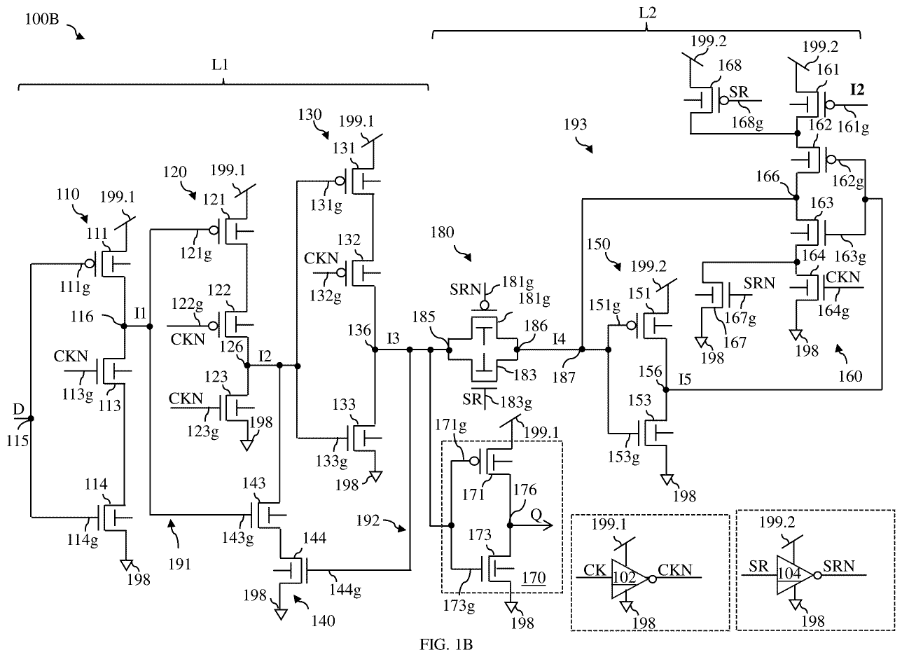

More particularly, FIGS. 1A and 1B are schematic diagrams illustrating embodiments of a structure 100A and 100B, respectively.

As described in greater detail below and illustrated in the figures, structure 100A, 100B can include portions that operate in two different voltage domains: a first voltage domain and a second voltage domain. Devices in the first voltage domain can be connected to a first positive supply voltage rail 199.1. In the first voltage domain, this first positive supply voltage rail 199.1 can be powered on (e.g., at a first positive supply voltage level (VDD)) or powered off (e.g., at ground, such as at 0.0 volts (V)) depending upon the operating mode. For example, in a normal operating mode, the first positive supply voltage rail 199.1 could be at VDD. VDD could be, for example, at 800.0 mV. Alternatively, VDD could be at any other suitable positive supply voltage level given the technology node within which the structure 100A, 100B is formed. In a data retention mode, the first positive supply voltage rail 199.1 could be powered down to 0.0 V. Devices in the second voltage domain can be connected to a second positive supply voltage rail 199.2. In the second voltage domain, this second positive supply voltage rail 199.2 can remain continuously powered on (e.g., at a second positive supply voltage level (VDDR)) regardless of operating mode. VDDR could, for example, also be at 800.0 mV. Alternatively, VDDR could be at any other suitable positive supply voltage level given the technology node within which the structure 100A, 100B is formed.

Structure 100A, 100B can be connected (e.g., to another on-chip component) to receive at least the following signals: a data input signal (D), a clock signal (CK), and an enable signal (also referred to herein as an enable signal for state retention (SR)). Structure 100A, 100B can include a clock signal inverter 102. For example, CK can be generated in the first voltage domain. Additionally, inverter 102 can include a P-type field effect transistor (PFET) and an N-type field effect transistor (NFET) connected in series between first positive supply voltage rail 199.1 and ground rail 198. In this inverter 102, gates of the PFET and NFET can be connected to receive CK and an output node at a junction between the PFET and NFET can output an inverted clock signal (CKN). Structure 100A, 100B can also include an enable signal inverter 104. For example, SR can be generated in the second voltage domain. Additionally, inverter 104 can include a PFET and an NFET connected in series between second positive supply voltage rail 199.2 and ground rail 198. In this inverter 104, gates of the PFET and NFET can be connected to receive SR and an output node at a junction between the PFET and NFET can output an inverted enable signal (also referred to herein as an inverted enable signal for state retention (SRN)).

Structure 100A, 100B can include a retention flip-flop. The retention flip-flop can include a first latch (L1) (also referred to herein as a primary latch) that operates in the first voltage domain; a second latch (L2) (also referred to herein as a secondary latch) that operates in the second voltage domain; and a switch 180, which includes terminals connected to L1 and to L2 so that L2 can be selectively connected to or disconnected from L1 and which also operates in the second voltage domain.

L1 can include four logic devices connected in series between data input node 115 and a data output node 176. The four logic devices can include: a first logic device 110; a second logic device 120, which is connected to first logic device 110 at a first intermediate node 116; a third logic device 130, which is connected to second logic device 120 at a second intermediate node 126; and a fourth logic device 170, which is connected to third logic device 130 at a third intermediate node 136 and which further includes data output node 176. L1 can additionally include a data retention structure including: a pair of transistors 143-144, which are connected in series to second intermediate node 126 and which have gates 143g and 144g connected to first intermediate node 116 and third intermediate node 136, respectively. L1 can be controlled by a single-phase clock signal (e.g., CKN, as illustrated).

More particularly, L1 can, as mentioned above, operate in the first voltage domain. Additionally, L1 can be controlled by a single-phase clock signal (e.g., by CKN only), as discussed in greater detail below.

L1 can further include first logic device 110. First logic device 110 can be a single-phase clock-controlled tri-state logic device. For purposes of this disclosure, a single-phase clock-controlled tri-state logic device is a tri-state logic device that outputs an output signal, which is high (i.e., logic 1, e.g., at approximately VDD), low (i.e., logic 0, e.g., at ground or 0.0V), or floating depending on the states of a single clock signal (e.g., CKN is this example) and a data input signal. A dual-phase clock-controlled tri-state logic device is a tri-state logic device that outputs an output signal, which is high (i.e., logic 1), low (i.e., logic 0), or floating depending on the states of two phases of the same clock signal (e.g., CK and CKN) and a data input signal.

In any first logic device 110 can include a stack of first transistors including a first PFET 111, a first NFET 113, and an additional first NFET 114, which are electrically connected in series between first positive supply voltage rail 199.1 and a ground rail 198 (e.g., at 0.0 volts (V)). Gate 111g of first PFET 111 and gate 114g of additional first NFET 114 can be electrically connected to a data input node 115 to receive a data input signal (D). Gate 113g of first NFET 113 can be electrically connected to receive CKN. First logic device 110 can further include a first intermediate node 116 at the junction between first PFET 111 and first NFET 113 (i.e., at the electrical connection between first PFET 111 and first NFET 113). A first intermediate signal (I1) can be output at first intermediate node 116. The state of I1 can be high, low, or floating depending upon the states of D and CKN.

L1 can further include second logic device 120. Second logic device 120 can also be a single-phase clock-controlled tri-state logic device. Specifically, second logic device 120 can include a stack of second transistors including a second PFET 121, an additional second PFET 122, and a second NFET 123, which are electrically connected in series between first positive supply voltage rail 199.1 and ground rail 198 (e.g., at 0.0 volts (V)). Gate 121g of second PFET 121 can be electrically connected to first intermediate node 116 to receive I1. Gates 122g and 123g of additional second PFET 122 and second NFET 123, respectively, can be electrically connected to receive CKN. Second logic device 120 can further include a second intermediate node 126 at the junction between additional second PFET 122 and second NFET 123 (i.e., at the electrical connection between additional second PFET 122 and second NFET 123). A second intermediate signal (I2) can be output at second intermediate node 126. The state of I2 can be high, low, or floating depending upon the states of I1 and CKN (and also depending upon a data retention structure 140, as discussed in greater detail below).

L1 can further include a third logic device 130. Third logic device 130 can also be a single-phase clock-controlled tri-state logic device. Specifically, third logic device 130 can include a stack of third transistors including a third PFET 131, an additional third PFET 132, and a third NFET 133, which are electrically connected in series between first positive supply voltage rail 199.1 and ground rail 198 (e.g., at 0.0 volts (V)). Gate 131g of third PFET 131 and gate 133g of third NFET 133 can be electrically connected to second intermediate node 126 to receive I2. Gate 132g of additional third PFET 132 can be electrically connected to receive CKN. Third logic device 130 can further include a third intermediate node 136 at the junction between additional third PFET 132 and third NFET 133 (i.e., at the electrical connection between additional third PFET 132 and third NFET 133). A third intermediate signal (I3) can be output at third intermediate node 136. The state of I3 can be high, low, or floating depending upon the states of I2 and CKN.

L1 can further include a fourth logic device 170. Fourth logic device 170 can include an inverter. Specifically, fourth logic device 170 can include a PFET 171 and an NFET 173, which are electrically connected in series between first positive supply voltage rail 199.1 and ground rail 198 (e.g., at 0.0 volts (V)). Gate 171g of PFET 171 and gate 173g of NFET 173 can be electrically connected to third intermediate node 136 to receive I3. This inverter can further include data output node 176 at a junction between PFET 171 and NFET 173 (i.e., at the electrical connection between PFET 171 and NFET 173). The state of a data output signal (Q) at data output node 176 will be high if I3 is low and low if I3 is high.

L1 can further include a data retention structure 140. Data retention structure 140 can include a pair of transistors 143-144, which are electrically connected in series to second intermediate node 126. Gates 143g and 144g of transistors 143 and 144 can be electrically connected to first intermediate node 116 for receiving I1 and third intermediate node 136 for receiving I3, respectively, effectively creating feedforward and feedback paths 191-192, respectively. More specifically, data retention structure 140 can include a fourth NFET 143 and an additional fourth NFET 144, which are electrically connected in series between second intermediate node 126 and ground rail 198. Gate 143g of fourth NFET 143 can be electrically connected to first intermediate node 116 such that the conductivity of fourth NFET 143 is controlled by I1 in feedforward path 191, whereas gate 144g of additional fourth NFET 144 can be electrically connected to third intermediate node 136 such that the conductivity of additional fourth NFET 144 is controlled by I3 in feedback path 192.

Switch 180 can have first and second end terminals 185 and 186, which are electrically connected to third intermediate node 136 of L1 and to L2, respectively. Switch 180 can further be configured to allow L1 to be selectively connected to or disconnected from L2 (e.g., depending upon the operating mode of structure 100A, 100B). For example, in a normal operating mode, switch 180 can operate to electrically connect L1 to L2 so that I3 passes to L2. In a data retention mode, switch 180 can operate to disconnect L1 from L2 so that I3 does not pass to L2. In some embodiments, switch 180 can be a transmission gate. That is, switch 180 can include a PFET 181 and an NFET 183 connected in parallel between the first and second terminals. The gate 181g of PFET 181 can be connected to receive SRN, whereas the gate 183gof NFET 183 can be connected to receive SR. Thus, when SR is high and SRN is low, switch 180 will be conductive (e.g., in a normal operating mode, as discussed in greater detail below with regard to retention flip-flop operation). However, when SR is low and SRN is high, switch 180 will be non-conductive (e.g., in a data retention mode, as discussed in greater detail below with regard to retention flip-flop operation). Since SR and SRN are generated by devices operating in the second voltage domain, switch 180 operates in the second voltage domain such that it remains functional even when VDD in first voltage domain is powered off.

L2 can, as mentioned above, also operate in the second voltage domain. L2 can include a fourth intermediate node 187. Fourth intermediate node 187 can be electrically connected to second end terminal 186 of switch 180. Thus, fourth intermediate node 187 of L2 will be electrically connected to third intermediate node 136 of L1 when switch 180 is conductive and disconnected therefrom when switch 180 is non-conductive. L2 can further include a keeper loop 193. Keeper loop 193 can include an inverter 150 and a tri-state logic device 160, which are connected in series from and back to fourth intermediate node 187.

More specifically, inverter 150 of keeper loop 193 in L2 can include a fifth PFET 151 and a fifth NFET 153, which are electrically connected in series between second positive supply voltage rail 199.2 in the second voltage domain and ground rail 198. Gates 151g and 153g of fifth PFET 151 and fifth NFET 153, respectively, can be electrically connected to fourth intermediate node 187. This inverter 150 can further include a fifth intermediate node 156 at a junction between fifth PFET 151 and fifth NFET 153 (i.e., at the electrical connection between fifth PFET 151 and fifth NFET 153). A fifth intermediate signal (I5) can be output at fifth intermediate node 156. The state of I5 will be high if I4 is low and low if I4 is high.

Tri-state logic device 160 of keeper loop 193 in L2 can include six transistors. In some embodiments, as illustrated in FIG. 1A, tri-state logic device 160 (and thereby L2 of structure 100A) can be controlled, in part, by a dual-phase clock signal (e.g., by both CK and CKN). More specifically, as discussed in greater detail below, tri-state logic device 160 of L2 of structure 100A can be controlled by a combination of CK, CKN, SR, SRN, and I5. In other embodiments, as illustrated in FIG. 1B, tri-state logic device 160 (and thereby L2 of structure 100B) can be controlled, in part, by a single-phase clock signal (i.e., by CKN only). More specifically, as discussed in greater detail below, tri-state logic device 160 of L2 of structure 100B can be controlled by a combination of I2, CKN, SR, SRN, and I5.

More particularly, in each of the disclosed embodiments, tri-state logic device 160 of keeper loop 193 can include: a sixth PFET 161, an additional sixth PFET 162, a sixth NFET 163, and an additional sixth NFET 164, which is electrically connected in series between second positive supply voltage rail 199.2 in the second voltage domain and ground rail 198. Tri-state logic device 160 can further include two additional transistors: a parallel sixth PFET 168 (and, more specifically, another sixth PFET that is connected in parallel with sixth PFET 161); and a parallel sixth NFET 167 (and, more specifically, another sixth NFET that is connected in parallel with additional sixth NFET 164). That is, parallel sixth PFET 168 can be electrically connected between second positive supply voltage rail 199.2 in the second voltage domain and a junction between sixth PFET 161 and additional sixth PFET 162 (i.e., at the electrical connection between sixth PFET 161 and additional sixth PFET 162). Similarly, parallel sixth NFET 167 can be electrically connected between a junction between sixth NFET 163 and additional sixth NFET 164 (i.e., at the electrical connection between sixth NFET 163 and additional sixth NFET 164) and ground rail 198.

In each of the embodiments, gates 162g and 163g of additional sixth PFET 162 and sixth NFET 163, respectively, can be electrically connected to fifth intermediate node 156 to receive I5. Additionally, a gate 168g of parallel sixth PFET 168 can be electrically connected to receive SR. A gate 167g of parallel sixth NFET 167 can be electrically connected to receive SRN. A gate 164g of additional sixth NFET 164 can be electrically connected to receive CKN.

In some embodiments, as illustrated in structure 100A of FIG. 1A, the desired inverter functionality can be achieved by tri-state logic device 160 using a dual-phase clock signal (e.g., both CK and CKN). That is, in addition to using CKN to control the conductivity of additional sixth NFET 164, a gate 161g of sixth PFET 161 can be electrically connected to receive CK. In other embodiments, as illustrated in structure 100B of FIG. 1B, the desired inverter functionality can be achieved by tri-state logic device 160 using a single-phase clock signal (e.g., CKN only). In this case, in addition to using CKN to control the conductivity of additional sixth NFET 164, gate 161g of sixth PFET 161 can be electrically connected to receive I2.

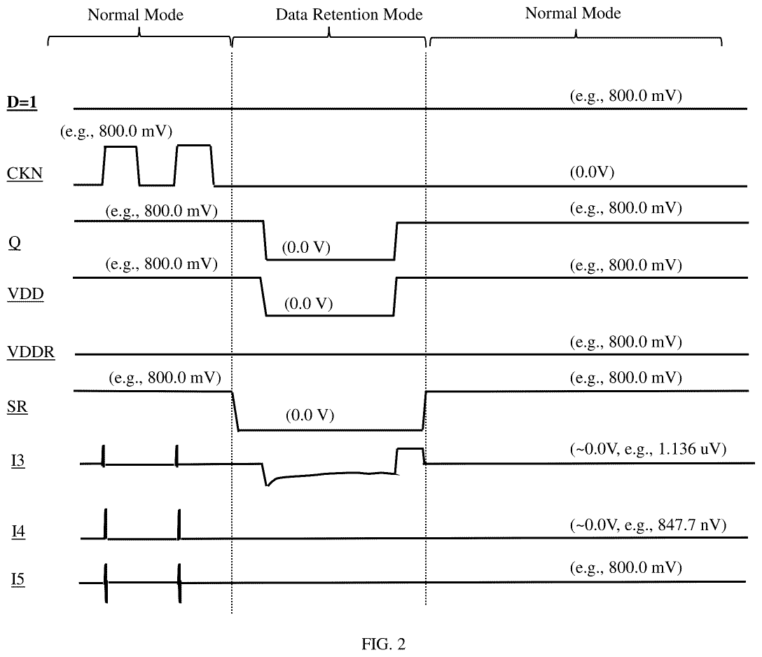

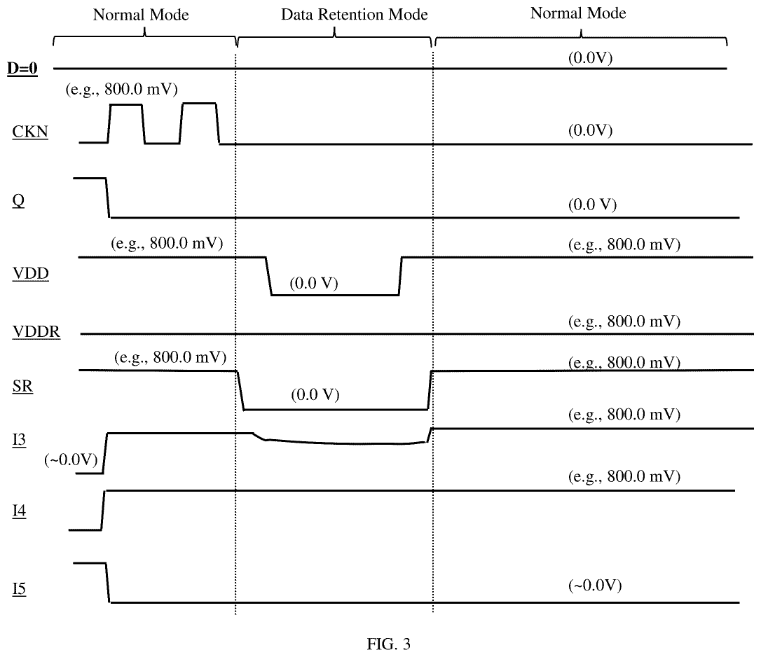

Methods of operating retention flip-flop of structure 100A of FIG. 1A and structure 100B in both a normal operating mode and a data retention mode are described in greater detail below with references to the timing diagrams of FIGS. 2 and 3.

FIG. 2 is a timing diagram illustrating operation of a retention flip-flop according to the disclosed embodiments in both a normal operating mode and a data retention mode when D received at data input node 115 has a logic value of 1. In the normal operating mode, SR will be high (e.g., at 800.0 mV) and SRN will be low (e.g., at 0.0 V) and, as a result, both PFET 181 and NFET 183 will be ON and L1 will be electrically connected to L2.

When D remains steady at a logic value of 1 (e.g., 800.0 mV) and VDD is powered on (e.g., at 800.0 mV) in the normal operating mode, Q will remain steady at a logic value of 1 (regardless of switching of CK and CKN). For example, when CKN is high and D is high, first PFET 111 will be OFF, first NFET 113 will be ON, and additional first NFET 114 will be ON. Thus, I1 will be pulled low. When CKN is high and I1 is low, second PFET 121 will be ON, additional second PFET 122 will be OFF, and second NFET 123 will be ON. Thus, I2 will be pulled low. When CKN is high and I2 is low, third PFET 133 is ON, additional third PFET 132 is OFF, and third NFET 133 is OFF, so I3 is floating (e.g., maintaining the state it had when CK was high and CKN was low). When CKN is low and D is high, first PFET 111 will be OFF, first NFET 113 will be ON, and additional first NFET 114 will be OFF. Thus, I1 will be floating and will maintain the state it had when CKN was high (i.e., I1 will stay low). When CKN is low and I1 is low, second PFET 121 will be ON, additional second PFET 122 will be ON, and second NFET 123 will be OFF. Thus, I2 will be pulled high. When CKN is low and I2 is high, third PFET 131 is OFF, additional third PFET 132 is ON, and third NFET 133 is ON, so I3 is pulled low. When I3 is low, Q is high. Since, as mentioned above, I3 has this same state when CKN is high, Q remains steady at a logic value of 1.

As mentioned above, in the normal operating mode, SR is high and SRN is low, so switch 180 is conductive such that I4 is essentially the same as I3 (e.g., at 0.0 V) and parallel PFET 168 and parallel NFET 167 are OFF. I5 is inverted with respect to I4 and, thus, high (e.g., at 800.0 mV) Thus, additional sixth PFET 162 is OFF and sixth NFET 163 is ON.

Referring specifically to structure 100A of FIG. 1A, during this normal operating mode when D is high and I5 is high, the states of CK and CKN are controlling. If CK is low and CKN is high when I5 is high (so additional sixth PFET 162 is OFF and sixth NFET 163 is ON), sixth PFET 161 will be ON and additional sixth NFET 164 will be ON. Thus, I4 will continue to be pulled down to ground through sixth intermediate node 166, sixth NFET 163, and additional sixth NFET 164 and so will I3 (through switch 180), to keep I3 from floating. However, if CK is high and CKN is low when I5 is high (so additional sixth PFET 162 is OFF and sixth NFET 163 is ON), sixth PFET 161 will be OFF and additional sixth NFET 164 will be OFF. Thus, sixth intermediate node 166 is left floating, to help avoid contention when I3 is driven by I2.

Referring specifically to structure 100B of FIG. 1B, during this normal operating mode when D is high and I5 is high, the states of I2 and CKN are controlling. As noted above, in this normal operating mode, when CKN is high, I2 is low and vice versa. So operation is essentially the same as described above with regard to structure 100A of FIG. 1A. That is, if I2 is low and CKN is high when I5 is high (so additional sixth PFET 162 is OFF and sixth NFET 163 is ON), sixth PFET 161 will be ON and additional sixth NFET 164 will be ON. Thus, I4 will continue to be pulled down to ground through sixth intermediate node 166, sixth NFET 163, and additional sixth NFET 164 and so will I3 (through switch 180), to keep I3 from floating. However, if I2 is high and CKN is low when I5 is high (so additional sixth PFET 162 is OFF and sixth NFET 163 is ON), sixth PFET 161 will be OFF and additional sixth NFET 164 will be OFF. Thus, sixth intermediate node 166 is left floating, to help avoid contention when I3 is driven by I2.

Referring again to the timing diagram of FIG. 2, the retention flip-flop can switch to the data retention mode by switching SR to low (e.g., 0.0V) and SRN to high (e.g., 800.0 mV). In this case, switch 180 will be non-conductive, effectively disconnecting L1 from L2. After switching of SR and SRN, VDD on first positive supply voltage rail 199.1 can be powered down (e.g., to 0.0 V). Without the power supply in L1, Q drops to 0.0V as do both CK and CKN. However, since VDDR on second positive supply voltage rail 199.2 stays powered on (e.g., at 800.0 mV) and SR and SRN have switched states, inverter 150 and tri-state logic device 160 in keeper loop 193 remain operative to that I4 continues to be pulled down to ground. Before the data retention mode is completed, VDD on first positive supply voltage rail 199.1 is powered back up (e.g., to 800.0 mV), so L1 and the clock signal generation circuit become operational pulling Q back to a logic value of 1. Then, SR and SRN can be switched back to the high and low voltage levels, respectively, to reinitiate the normal operating mode.

FIG. 3 is a timing diagram illustrating operation of a retention flip-flop according to the disclosed embodiments in both a normal operating mode and a data retention mode when D received at data input node 115 switches from logic value of 1 to logic value of 0 and, then remains steady at D=0. In the normal operating mode, SR will be high (e.g., at 800.0 mV) and SRN will be low (e.g., at 0.0 V) and, as a result, both PFET 181 and NFET 183 will be ON and L1 will be electrically connected to L2. Additionally, Q only switches to the logic value of 0 on the rising edge of CKN and then remains steady at Q=0 (regardless of switching of CK and CKN) as long as D=0.

For example, when CKN goes high and D is low, first PFET 111 will be ON, first NFET 113 will be ON, and additional first NFET 114 will be OFF. Thus, I1 will be pulled high. When CKN is high and I1 is high, second PFET 121 will be OFF, additional second PFET 122 will be OFF, and second NFET 123 will be ON. Thus, I2 will be pulled low. When CKN is high and I2 is low, third PFET 133 is ON, additional third PFET 132 is OFF, and third NFET 133 is OFF, so I3 is floating (e.g., maintaining the state it had when CK was high and CKN was low).

When CKN is low and D is low, first PFET 111 will be ON, first NFET 113 will be OFF, and additional first NFET 114 will be OFF. Thus, I1 will be pulled high. When CKN is low and I1 is high, second PFET 121 will be OFF, additional second PFET 122 will be ON, and second NFET 123 will be OFF. Thus, I2 will be floating (e.g., maintaining the state it had when CK was low and CKN was high) and, thereby low. When CKN is low and I2 is low, third PFET 133 is ON, additional third PFET 132 is ON, and third NFET 133 is OFF, so I3 is pulled high. When I3 is high, Q is low. Since, as mentioned above, I3 has this same state when CKN is high, Q remains steady at a logic value of 0.

As mentioned above, in the normal operating mode, SR is high and SRN is low, so switch 180 is conductive such that I4 is essentially the same as I3 (e.g., at 800.0 mV) and parallel PFET 168 and parallel NFET 167 are OFF. I5 is inverted with respect to I4 and, thus, low (e.g., at 0.0 V). So, additional sixth PFET 162 is ON and sixth PFET 163 is OFF.

Referring specifically to structure 100A of FIG. 1A, during this normal operating mode when D is low and I5 is low, the states of CK and CKN are controlling. If CK is low and CKN is high when I5 is low (so additional sixth PFET 162 is ON and sixth NFET 163 is OFF), sixth PFET 161 will be ON and additional sixth NFET 164 will be OFF. Thus, the voltage level of I4 will continue to be pulled up through sixth intermediate node 166, additional sixth PFET 162, and sixth PFET 161. Furthermore, voltage level of I3 will continue to be pulled up through switch 180. However, if CK is high and CKN is low when I5 is low (so additional sixth PFET 162 is ON and sixth NFET 163 is OFF), sixth PFET 161 will be OFF and additional sixth NFET 164 will be ON. Thus, sixth intermediate node 166 is left floating.

Referring specifically to structure 100B of FIG. 1B, during this normal operating mode when D is high and I5 is low, the states of I2 and CKN are controlling. As noted above, in this normal operating mode, when CKN is high, I2 is low and vice versa. So operation is essentially the same as described above with regard to structure 100A of FIG. 1A. That is, if I2 is low and CKN is high when I5 is low (so additional sixth PFET 162 is ON and sixth NFET 163 is OFF), sixth PFET 161 will be ON and additional sixth NFET 164 will be OFF. Thus, the voltage level of I4 will continue to be pulled up, through sixth intermediate node 166, additional sixth PFET 162 and sixth PFET 161. However, if I2 is high and CKN is low when I5 is low (so additional sixth PFET 162 is ON and sixth NFET 163 is OFF), sixth PFET 161 will be OFF and additional sixth NFET 164 will be ON. Thus, sixth intermediate node 166 is left floating. This helps avoid contention issues. When I2 is driving I3, keeper loop 193 (also referred to herein as a feedback loop) is turned off. In other words, feedback loop is turned on only when I2 is not driving I3 to keep node I3 from floating.

Referring again to the timing diagram of FIG. 3, the retention flip-flip can switch to the data retention mode by switching SR to low (e.g., 0.0V) and SRN to high (e.g., 800.0 mV). In this case, switch 180 will be non-conductive, effectively disconnecting L1 from L2. After SR and SRN are switched, VDD on first positive supply voltage rail 199.1 can be powered down (e.g., to 0.0 V), Q remains at 0.0V and CK and CKN will both be at 0.0 V. However, since VDDR on second positive supply voltage rail 199.2 stays powered on (e.g., at 800.0 mV) and SR and SRN have switched states, inverter 150 and tri-state logic device 160 in keeper loop 193 remain operative so that I4 stays high. Before the data retention mode is completed, VDD on first positive supply voltage rail 199.1 is powered back up (e.g., to 800.0 mV), so L1 and the clock signal generation circuit become operational. Then, SR and SRN can be switched back to the high and low voltage levels, respectively, to reinitiate the normal operating mode.

It should be noted that second intermediate node 126 in L1 of structure 100A of FIG. 1A or structure 100B of FIG. 1B can also be referred to as a data transfer node. Feedforward path 191 and feedback path 192 ensure that I2 does not change states and, particularly, rise under certain conditions so that Q also does not change states. For example, When CKN is low and I1 is high, second PFET 121 will be OFF, additional second PFET 122 will be ON, and second NFET 123 will be OFF. Thus, I2 will be floating (e.g., maintaining the state it had when CK was low and CKN was high) and, thereby low. When CKN is low and I2 is low, third PFET 133 is ON, additional third PFET 132 is ON, and third NFET 133 is OFF, so I3 is pulled high. When I1 is high, fourth NFET 143 will be ON. When I3 is high, the additional fourth NFET 144 will be ON. These two NFET ON will help pull I2 LOW thus averting I2 from floating (as in without these two NFET.

Thus, within structure 100A of FIG. 1A and structure 100B of FIG. 1B, the combination of feedforward path 191 and feedback path 192 in L1 and keeper loop 193 in L2 effectively prevent data loss if/when CKN is static for some extended period of time (i.e., in the absence of clock edges for a prolonged period) by ensuring that I2 and I3 retain their current states if/when second intermediate node 126 and/or third intermediate node 136, respectively, are floating. Thus, the combination of feedforward path 191, feedback path 192, and feedback loop 193 ensure that, during the normal operating mode, Q only switches on the rising edge of CKN. Furthermore, in the data retention mode, L2 ensures that the last data value received is captured when L1 is powered down and held until L1 is powered back on.

It should be understood that in the embodiments described above a field effect transistor (FET) is a semiconductor device including a channel region between source/drain regions, a primary gate (also referred to in the art as a front gate) adjacent to the channel region, and, optionally, a secondary gate (also referred to in the art as a back gate) adjacent to the channel region opposite the primary gate. A P-type FET (PFET) can include P-type source/drain regions at a relatively high conductivity level (e.g., P+ source/drain regions) and a channel region that is either an intrinsic (i.e., undoped) channel region or an N-type channel region at a relatively low conductivity level (e.g., a N-channel region). An N-type FET (NFET) can include N-type source/drain regions at a relatively high conductivity level (e.g., N+ source/drain regions) and a channel region that is either an intrinsic (i.e., undoped) channel region or a P-type channel region at a relatively low conductivity level (e.g., a P-channel region). Various different types of FET structures are known in the art and could be incorporated into the disclosed circuit structures. For example, the FETs mentioned above could be bulk semiconductor devices or semiconductor-on-insulator devices, planar semiconductor devices or non-planar semiconductor devices, single gate devices or dual-gate devices, single gate finger devices or multiple gate finger devices, etc.

In some embodiments, the FETs of the structure 100A, 100B could be formed using an advanced semiconductor-on-insulator technology processing platform such that they are either fully-depleted semiconductor-on-insulator FETs (e.g., a fully-depleted SOI (FDSOI) FET) or partially-depleted semiconductor-on-insulator FETs (e.g., a partially-depleted SOI (PDSOI) FET). Those skilled in the art will recognize that one advantage of advanced semiconductor-on-insulator technology processing platforms is that FETs can be formed on an insulator layer above a particular type of well region (e.g., an N-type well region (Nwell) or a P-type well region (Pwell)) in order to achieve different types of NFETs or PFETs with different threshold voltages (VTs). For example, for a super low threshold voltage (SLVT) or low threshold voltage (LVT) FET, an NFET can be formed above an Nwell and a PFET can be formed above a Pwell. For a regular threshold voltage (RVT) or high threshold voltage (HVT) FET, an NFET can be formed above a Pwell and a PFET can be formed above an Nwell. Whether the FETs are SLVT or LVT FETs or whether they are RVT or HVT FETs will depend upon the design (e.g., device size, etc.) and process specifications (e.g., dopant concentrations, etc.). In some embodiments, the FETs within structure 100A, 100B can be all RVT or HVT FETs. That is, within structure 100A, 100B, PFETs can be above Nwells and NFETs can be above Pwells.

Configured, as described in greater detail below and illustrated in FIGS. 1A and 1B, the retention flip-flops of structure 100A and 100B include a total of twenty-seven transistors (which is less than the thirty or more typically seen in retention flip-flops). Thus, they may consume less chip area (e.g., a 5-10% reduction in chip area). Additionally, configured, as described in greater detail below and illustrated in FIGS. 1A and 1B, the retention flip-flops of structure 100A and 100B may exhibit: (a) a reduction (e.g., of 20-40% or more) in both VDD leakage current and VDDR leakage current; and/or (b) improved performance (e.g., a reduced clock to Q delay of 10-20% or more) as compared to conventional retention flip-flops.

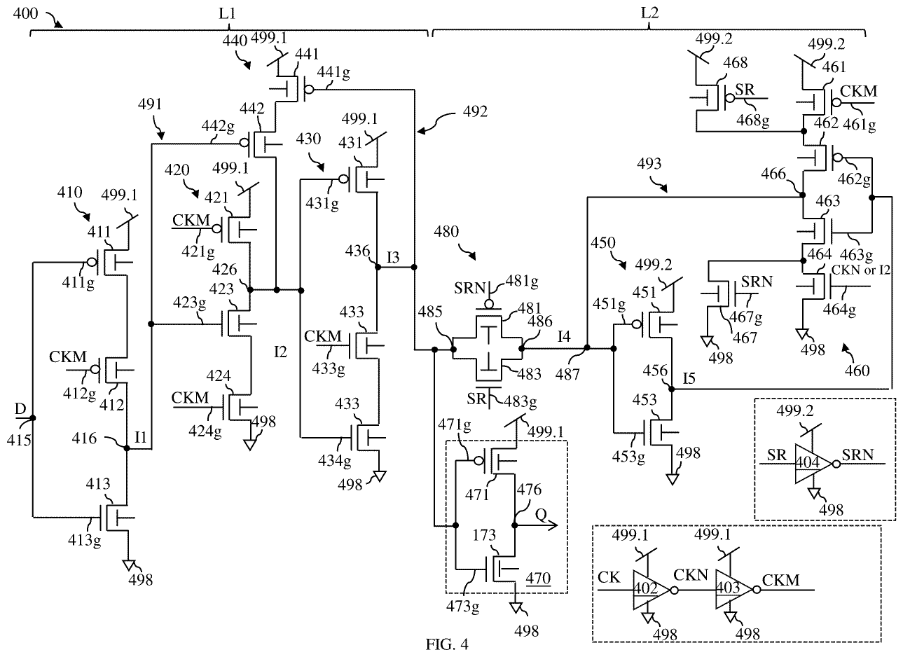

It should be noted that the structure embodiments including a retention flip-flop illustrated in FIGS. 1A and 1B are provided for illustration purposes and are not intended to be limiting. Alternatively, an embodiment of the structure 400 as illustrated in FIG. 4 could be flipped relative to the structures shown in FIGS. 1A and 1B. The structure 400 of FIG. 4 similarly includes: a first latch (L1), which operates in a first voltage domain, is powered on during a normal operating mode, and is powered off in a data retention mode; a second latch (L2), which operates in a second voltage domain and remains continuously powered on regardless of the mode; and a switch 480 (e.g., a transmission gate) connected between L1 and L2. L1 can include a data retention structure 440 (including a combination of feedforward and feedback paths 491-492) configured to avoid data loss when a single-phase clock signal (e.g., CKM, as discussed below) that controls flip-flop operation is static for some extended period of time. L2 can include a keeper loop 493 configured to avoid data loss when the first voltage domain is powered off. L2 can be controlled, in part, by a dual-phase clock signal (CKM and CKN, which is inverted relative to CKM, as discussed below) or, in part, by a combination of CKM and an intermediate signal from a node within L1.

More particularly, as with structures 100A, 100B, structure 400 can be connected to receive the following signals: D, CK, and SR. Structure 400 can include a pair of series-connected clock signal inverters 402-403 in first voltage domain (i.e., connected to a first positive supply voltage rail 499.1, which can be powered down). Clock signal inverters 402-403 can generate CKN, which is inverted relative to CK, and CKM, which is inverted relative to CKN, respectively. Structure 400 can also include an enable signal inverter 404 in a second voltage domain (i.e., connected to a second positive supply voltage rail 499.2, which remains powered on). Inverter 404 can generate SRN, which is inverted relative to SR. Structure 400 can also include retention flip-flop including a first latch (L1), a second latch (L2), and switch 480 therebetween.

L1 can further include first logic device 410. First logic device 410 can be a single-phase clock-controlled tri-state logic device and can include a stack of first transistors. The first transistors can include a first PFET 411, an additional first PFET 412, and a first NFET 413, which are electrically connected in series between first positive supply voltage rail 499.1 and a ground rail 498 (e.g., at 0.0 volts (V)). Gate 411g of first PFET 411 and gate 413g of l first NFET 413 can be electrically connected to a data input node 415 to receive D. Gate 412g of additional first PFET 412 can be electrically connected to receive CKM. First logic device 410 can further include a first intermediate node 416 at the junction between additional first PFET 412 and first NFET 413. A first intermediate signal (I1) can be output at first intermediate node 416. The state of I1 can be high, low, or floating depending upon the states of D and CKM.

L1 can further include second logic device 420. Second logic device 120 can also be a single-phase clock-controlled tri-state logic device and can include a stack of second transistors. The second transistors can include a second PFET 421, a second NFET 423, and an additional second NFET 424, which are electrically connected in series between first positive supply voltage rail 499.1 and ground rail 498 (e.g., at 0.0 volts (V)). Gate 421g of second PFET 421 and gate 424 of additional second NFET 424 can be electrically connected to receive CKM. Gate 423g of second NFET 423 can be electrically connected to receive to first intermediate node 416 to receive I1. Second logic device 120 can further include a second intermediate node 426 at the junction between second PFET 421 and second NFET 423. A second intermediate signal (I2) can be output at second intermediate node 426. The state of I2 can be high, low, or floating depending upon the states of I1 and CKM (and also depending upon a data retention structure 440, discussed in greater detail below).

L1 can further include a third logic device 430. Third logic device 130 can also be a single-phase clock-controlled tri-state logic device and can include a stack of third transistors. The third transistors can include a third PFET 431, a third NFET 433, and an additional third NFET 434, which are electrically connected in series between first positive supply voltage rail 499.1 and ground rail 498 (e.g., at 0.0 volts (V)). Gate 431g of third PFET 431 and gate 434g of additional third NFET 434 can be electrically connected to second intermediate node 426 to receive I2. Gate 433g of third NFET 433 can be electrically connected to receive CKM. Third logic device 430 can further include a third intermediate node 436 at the junction between third PFET 431 and third NFET 433. A third intermediate signal (I3) can be output at third intermediate node 436. The state of I3 can be high, low, or floating depending upon the states of I2 and CKM.

L1 can further include a fourth logic device 470. Fourth logic device 470 can include an inverter. Specifically, fourth logic device 470 can include a PFET 471 and an NFET 473, which are electrically connected in series between first positive supply voltage rail 499.1 and ground rail 498 (e.g., at 0.0 volts (V)). Gate 471g of PFET 471 and gate 473g of NFET 473 can be electrically connected to third intermediate node 436 to receive I3. This inverter can further include data output node 476 at a junction between PFET 471 and NFET 473. The state of a data output signal (Q) at data output node 476 will be high if I3 is low and low if I3 is high.

L1 can further include a data retention structure 440. Data retention structure 440 can include a pair of PFETs 441-442, which are electrically connected in series between first positive supply voltage rail 499.1 and second intermediate node 426. Gates 441g and 442g of PFETs 441 and 442 can be electrically connected to third intermediate node 436 for receiving I3 and first intermediate node 416 for receiving I1, respectively, effectively creating feedback path 492 and feedforward path 491, respectively.

Switch 480 operate in the second voltage domain and can have first and second end terminals 485 and 486, which are electrically connected to third intermediate node 436 of L1 and to L2, respectively. Switch 480 can be configured to allow L1 to be selectively connected to or disconnected from L2 (e.g., depending upon the operating mode of structure 400). In some embodiments, switch 480 can be a transmission gate. That is, switch 480 can include a PFET 481 and an NFET 483 connected in parallel between the first and second terminals. The gate 481g of PFET 481 can be connected to receive SRN, whereas the gate 483g of NFET 483 can be connected to receive SR. Thus, when SR is high and SRN is low, switch 480 will be conductive (e.g., in a normal operating mode). However, when SR is low and SRN is high, switch 480 will be non-conductive (e.g., in a data retention mode).

L2 can, as mentioned above, can also operate in the second voltage domain. L2 can include a fourth intermediate node 487 electrically connected to second end terminal 486 of switch 480. Thus, fourth intermediate node 487 of L2 will be electrically connected to third intermediate node 436 of L1 when switch 480 is conductive and disconnected therefrom when switch 480 is non-conductive. L2 can further include a keeper loop 493. Keeper loop 493 can include an inverter 450 and a tri-state logic device 460, which are connected in series from and back to fourth intermediate node 487.

More specifically, inverter 450 of keeper loop 493 in L2 can include a fifth PFET 451 and a fifth NFET 453, which are electrically connected in series between second positive supply voltage rail 499.2 in the second voltage domain and ground rail 498. Gates 451g and 453g of fifth PFET 451 and fifth NFET 453, respectively, can be electrically connected to fourth intermediate node 487. This inverter 450 can further include a fifth intermediate node 456 at a junction between fifth PFET 451 and fifth NFET 453. A fifth intermediate signal (I5) can be output at fifth intermediate node 456. The state of I5 will be high if I4 is low and low if I4 is high.

Tri-state logic device 460 of keeper loop 493 in L2 can include six transistors. These six transistors can include: a sixth PFET 461, an additional sixth PFET 462, a sixth NFET 463, and an additional sixth NFET 464, which is electrically connected in series between second positive supply voltage rail 499.2 in the second voltage domain and ground rail 498. Inverter 460 can further include two additional transistors: a parallel sixth PFET 468 (and, more specifically, another sixth PFET that is connected in parallel with sixth PFET 461); and a parallel sixth NFET 467 (and, more specifically, another sixth NFET that is connected in parallel with additional sixth NFET 464). That is, parallel sixth PFET 468 can be electrically connected between second positive supply voltage rail 499.2 in the second voltage domain and a junction between sixth PFET 461 and additional sixth PFET 462. Similarly, parallel sixth NFET 467 can be electrically connected between a junction between sixth NFET 463 and additional sixth NFET 464 and ground rail 498.

Gates 462g and 463g of additional sixth PFET 462 and sixth NFET 463, respectively, can be electrically connected to fifth intermediate node 456 to receive I5. Additionally, a gate 468g of parallel sixth PFET 468 can be electrically connected to receive SR. A gate 467g of parallel sixth NFET 467 can be electrically connected to receive SRN. A gate 461g of sixth PFET 461 can be electrically connected to receive CKM. A gate 464g of additional sixth NFET 464 can be connected to receive CKN (which is inverted relative to CK) or, alternatively, I2. A sixth intermediate node 466 at a junction between additional sixth PFET 462 and sixth NFET 463 can be electrically connected to fourth intermediate node 487.

Those skilled in the art will recognize that operation of the retention flip-flop in structure 400 of FIG. 4 will be similar to operation of the retention flip-flop in the structures 100A or 100B of FIGS. 1A-1B.

It should be understood that in the method and structures described above, a semiconductor material refers to a material whose conducting properties can be altered by doping with an impurity. Example semiconductor materials include, but are not limited to, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms “a,” “an” and “the” are intended to include the plural forms as well, unless the context clearly indicates otherwise. Additionally, as used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first latch including:
four logic devices connected between a data input node and a data output node, wherein the four logic devices include: a first logic device; a second logic device connected to a first intermediate node of the first logic device; a third logic device connected to a second intermediate node of the second logic device; and a fourth logic device connected to a third intermediate node of the third logic device; and
a data retention structure including: a pair of transistors connected in series to the second intermediate node and having gates connected to the first intermediate node and the third intermediate node, respectively;
a second latch; and
a switch with a first terminal connected to the third intermediate node and a second terminal connected to a fourth intermediate node of the second latch.

2. The structure of claim 1,
wherein the first latch is in a first voltage domain and controlled by a single-phase clock signal, and
wherein the second latch is in a second voltage domain and controlled, in part, by one of:
a dual-phase clock signal; and
the single-phase clock signal and a voltage level on the second intermediate node.

3. The structure of claim 1,
wherein the first logic device, the second logic device, and the third logic device include single-phase clock-controlled tri-state logic devices, and
wherein the fourth logic device includes an inverter.

4. The structure of claim 3,
wherein the first logic device includes a first P-type field effect transistor (PFET), a first N-type field effect transistor (NFET), and an additional first NFET connected in series between a positive supply voltage rail in a first voltage domain and ground,
wherein gates of the first PFET and the additional first NFET are connected to the data input node, and
wherein a gate of the first NFET is connected to receive an inverted clock signal.

5. The structure of claim 4,
wherein the second logic device includes a second PFET, an additional second PFET, and a second NFET connected in series between the positive supply voltage rail in the first voltage domain and ground,
wherein a gate of the second PFET is connected to the first intermediate node at a junction between the first PFET and the first NFET, and
wherein a gate of the additional second PFET is connected and a gate of the second NFET are connected to receive the inverted clock signal.

6. The structure of claim 5,
wherein the third logic device includes a third PFET, an additional third PFET, and a third NFET connected in series between the positive supply voltage rail in the first voltage domain and ground,
wherein a gate of the third PFET and a gate of the third NFET are connected to the second intermediate node at a junction between the additional second PFET and the second NFET,
wherein a gate of the additional third PFET is connected to receive the inverted clock signal, and
wherein the third intermediate node is at a junction between the additional third PFET and the third NFET.

7. The structure of claim 6,
wherein the pair of transistors of the data retention structure include a fourth NFET and an additional fourth NFET connected in series between the second intermediate node and ground,
wherein a gate of the fourth NFET is connected to the first intermediate node, and
wherein a gate of the additional fourth NFET is connected to the third intermediate node.

8. The structure of claim 1, wherein the switch includes a transmission gate controlled by an enable signal and an inverted enable signal, and wherein the second latch is controlled by a clock signal, an inverted clock signal, the enable signal, and the inverted enable signal.

9. The structure of claim 8, wherein the second latch includes a keeper loop including an inverter and a tri-state logic device connected in series from and back to the fourth intermediate node.

10. The structure of claim 9,
wherein the inverter of the keeper loop includes a fifth PFET and a fifth NFET connected in series between a positive supply voltage rail in a second voltage domain and ground,
wherein gates of the fifth PFET and the fifth NFET are connected to the fourth intermediate node,
wherein the tri-state logic device of the keeper loop includes:
a sixth PFET, an additional sixth PFET, a sixth NFET, and an additional sixth NFET connected in series between the positive supply voltage rail in the second voltage domain and ground;
a parallel sixth PFET connected between the positive supply voltage rail in the second voltage domain and a junction between the sixth PFET and the additional sixth PFET; and
a parallel sixth NFET connected between a junction between the sixth NFET and the additional sixth NFET and ground,
wherein gates of the additional sixth PFET and the sixth NFET are connected to a fifth intermediate node at a junction between the fifth PFET and the fifth NFET,
wherein a gate of the sixth PFET is connected to receive the clock signal,
wherein a gate of the additional sixth NFET is connected to receive the inverted clock signal,
wherein a gate of the parallel sixth PFET is connected to receive the enable signal, and
wherein a gate of the parallel sixth NFET is connected to receive the inverted enable signal.

11. A structure comprising:
a first latch in a first voltage domain, wherein the first latch includes:
four logic devices connected between a data input node and a data output node, wherein the four logic devices include: a first logic device; a second logic device connected to a first intermediate node of the first logic device; a third logic device connected to a second intermediate node of the second logic device; and a fourth logic device connected to a third intermediate node of the third logic device; and
a data retention structure including: a pair of N-type field effect transistors (NFETs) connected in series to the second intermediate node and having gates connected to the first intermediate node and the third intermediate node, respectively;
a second latch in a second voltage domain; and
a switch with a first terminal connected to the third intermediate node and a second terminal connected to a fourth intermediate node of the second latch.

12. The structure of claim 11,
wherein the first latch is controlled by a single-phase clock signal, and
wherein the second latch is controlled, in part, by one of:
a dual-phase clock signal; and
the single-phase clock signal and a voltage level on the second intermediate node.

13. The structure of claim 11,
wherein the first logic device, the second logic device, and the third logic device include single-phase clock-controlled tri-state logic devices, and
wherein the fourth logic device includes an inverter.

14. The structure of claim 13,
wherein the first logic device includes a first P-type field effect transistor (PFET), a first N-type field effect transistor (NFET), and an additional first NFET connected in series between a positive supply voltage rail in the first voltage domain and ground,
wherein gates of the first PFET and the additional first NFET are connected to the data input node,
wherein a gate of the first NFET is connected to receive an inverted clock signal,
wherein the second logic device includes a second PFET, an additional second PFET, and a second NFET connected in series between the positive supply voltage rail in the first voltage domain and ground,
wherein a gate of the second PFET is connected to the first intermediate node at a junction between the first PFET and the first NFET, and
wherein a gate of the additional second PFET is connected and a gate of the second NFET are connected to receive the inverted clock signal.

15. The structure of claim 14,
wherein the third logic device includes a third PFET, an additional third PFET, and a third NFET connected in series between the positive supply voltage rail in the first voltage domain and ground,
wherein a gate of the third PFET and a gate of the third NFET are connected to the second intermediate node at a junction between the additional second PFET and the second NFET,
wherein a gate of the additional third PFET is connected to receive the inverted clock signal, and
wherein the third intermediate node is at a junction between the additional third PFET and the third NFET.

16. The structure of claim 15,
wherein the pair of NFETs of the data retention structure include a fourth NFET and an additional fourth NFET connected in series between the second intermediate node and ground,
wherein a gate of the fourth NFET is connected to the first intermediate node, and
wherein a gate of the additional fourth NFET is connected to the third intermediate node.

17. The structure of claim 11, wherein the switch includes a transmission gate controlled by an enable signal and an inverted enable signal.

18. The structure of claim 17, wherein the first latch is controlled by an inverted clock signal and wherein the second latch is controlled by the inverted clock signal, a voltage level on the second intermediate node, the enable signal, and the inverted enable signal.

19. The structure of claim 18,
wherein the second latch includes a keeper loop including an inverter and tri-state logic device connected in series from and back to the fourth intermediate node,
wherein the inverter of the keeper loop includes a fifth PFET and a fifth NFET connected in series between a positive supply voltage rail in the second voltage domain and ground,
wherein gates of the fifth PFET and the fifth NFET are connected to the fourth intermediate node,
wherein the tri-state logic device of the keeper loop includes:
a sixth PFET, an additional sixth PFET, a sixth NFET, and an additional sixth NFET connected in series between the positive supply voltage rail in the second voltage domain and ground;
a parallel sixth PFET connected between the positive supply voltage rail in the second voltage domain and a junction between the sixth PFET and the additional sixth PFET; and
a parallel sixth NFET connected between a junction between the sixth NFET and the additional sixth NFET and ground,
wherein gates of the additional sixth PFET and the sixth NFET are connected to a fifth intermediate node at a junction between the fifth PFET and the fifth NFET,
wherein a gate of the sixth PFET is connected to the second intermediate node,
wherein a gate of the additional sixth NFET is connected to receive the inverted clock signal,
wherein a gate of the parallel sixth PFET is connected to receive the enable signal, and
wherein a gate of the parallel sixth NFET is connected to receive the inverted enable signal.

20. A structure comprising:
a first latch in a first voltage domain, wherein the first latch includes:
four logic devices connected between a data input node and a data output node, wherein the four logic devices include a first logic device, a second logic device connected to the first logic device at a first intermediate node, a third logic device connected to the second logic device at a second intermediate node, and a fourth logic device connected to the third logic device at a third intermediate node; and
a data retention structure including: a pair of P-type field effect transistors (PFETs) connected in series to the second intermediate node and having gates connected to the first intermediate node and the third intermediate node, respectively;
a second latch in a second voltage domain; and
a switch with a first terminal connected to the third intermediate node and a second terminal connected to a fourth intermediate node of the second latch.
